(19) United States
(12) Patent Application Publication
(10) Pub. No.: US 2014/0175030 A1
(43) Pub. Date: Jun. 26, 2014

(54) SERVER RACK

(71) Applicant: Tung Ke Lu, New Taipei City (TW)

(72) Inventor: Tung Ke Lu, New Taipei City (TW)

(73) Assignee: GIGA-BYTE TECHNOLOGY CO., LTD.

(21) Appl. No.: 13/723,182

(22) Filed: Dec. 20, 2012

(51) Int. Cl. H05K 7/18

(52) U.S. Cl. CPC H05K 7/18
USPC 211/26

(57) ABSTRACT

A server rack includes support pillars, module kits and fixing components. Each support pillar includes plural first mounting holes. Each of the module kits includes at least one mounting portion which has at least one second mounting hole. The second mounting hole is corresponding to the first mounting hole, and the fixing component passes through the first mounting hole and the second mounting hole, so as to fix the corresponding module kit on the server rack by the mounting portion.

### CROSS-REFERENCES TO RELATED APPLICATIONS

This non-provisional application claims priority under 35 U.S.C. §119(a) on Patent Application No. 101129958 filed in Taiwan, R.O.C. on 2012 Aug. 17, the entire contents of which are hereby incorporated by reference.

### BACKGROUND

1. Technical Field

This disclosure is related to a server rack, and more particularly related to a modular server rack.

2. Related Art

The cloud computing service technology is the current trend of technological evolution. The cloud service technology relies on the large number of servers. Therefore, the cloud computing service provider needs to set up many servers, such as a Web server, an e-mail server, a database server, or a data server to satisfy the requirement of the cloud computing service. A server rack is usually required to conveniently dispose these servers therein. Generally, the conventional server rack has the advantages of excellent heat dissipation efficiency and easily to storage the large number of servers.

FIG. 1 is a schematic view of a conventional server rack. As shown in FIG. 1, the conventional server rack 100 includes a server setting region 102, a communication line region 104 and a cooling region 106. These regions have been planned before the server rack 100 shipping, thus these regions' position is very difficult to change. For example, if we want to narrow range of the communication line region 104, or want to increase range of the cooling region 106, each region of the conventional server rack must be redesigned to satisfy the foregoing purposes. On the other hand, there are many manufacturers manufacturing the server, thus there can be found various servers in the market, and server rack structure is a very complex system design, hence it's could be very difficult to assemble the various servers.

Therefore, there is a need to design a server rack that provide the function can be arbitrarily change the regions' position therein, so as to solve the above problems to improve the convenience of use in the server rack.

### SUMMARY

In view of the forgoing problems, this disclosure provides a server rack, which is configured to simplify the assembly structure by a modular design, and also easily to maintain a server in the future.

In one or more embodiments of this disclosure, a server rack includes plural support pillars, plural module kits and plural fixing components. Each of the support pillars has plural first mounting holes, each of the module kits has at least one mounting portion, and each of the mounting portions has a second mounting hole corresponding to one of the first mounting holes. The fixing components pass through the first mounting holes and the second mounting hole respectively, so as to fix each of the module kits on the server rack by the mounting portion.

In one or more embodiment of this disclosure, a server rack includes plural support pillars, plural module kits and plural fixing components. Each of the support pillars has plural first mounting holes, each of the module kits has at least one mounting portion which extends along a longitudinal direction from two ends of the module kit. The mounting portion is selectively assembled to or separated from the support pillar, and each of the mounting portions has a second mounting hole corresponding to one of the first mounting holes. Each of the fixing components has an inclined plane disposed on top portion of the fixing component. The fixing components align and pass through the first mounting holes and the second mounting hole respectively by the inclined plane, so as to fix each of the module kits on the server rack.

### BRIEF DESCRIPTION OF THE DRAWINGS

This disclosure will become more fully understood from the detailed description given herein below for illustration only, and thus not limitative of the claim scope, wherein:

FIG. 1 is a schematic view of a conventional server rack.

FIG. 2A is an exploded view of a server rack according to an embodiment of this disclosure.

FIG. 2B is a schematic view of a bus bar kit according to the server rack of this disclosure.

FIG. 3A is a partially schematic view of the embodiment of this disclosure.

FIG. 3B is a cross-sectional view of the embodiment of this disclosure.

FIG. 3C is a partially cross-sectional view of FIG. 3B.

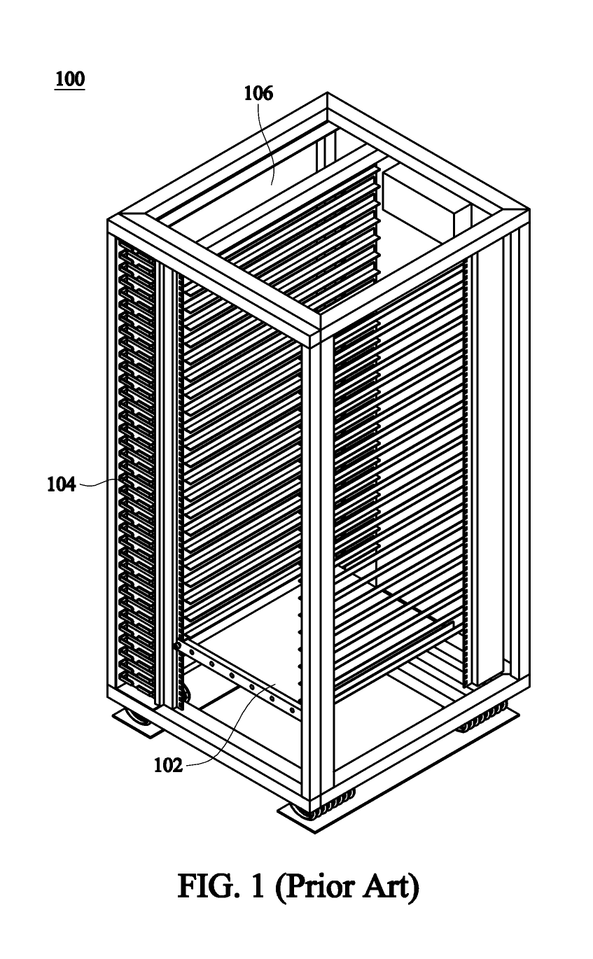

### DETAILED DESCRIPTION

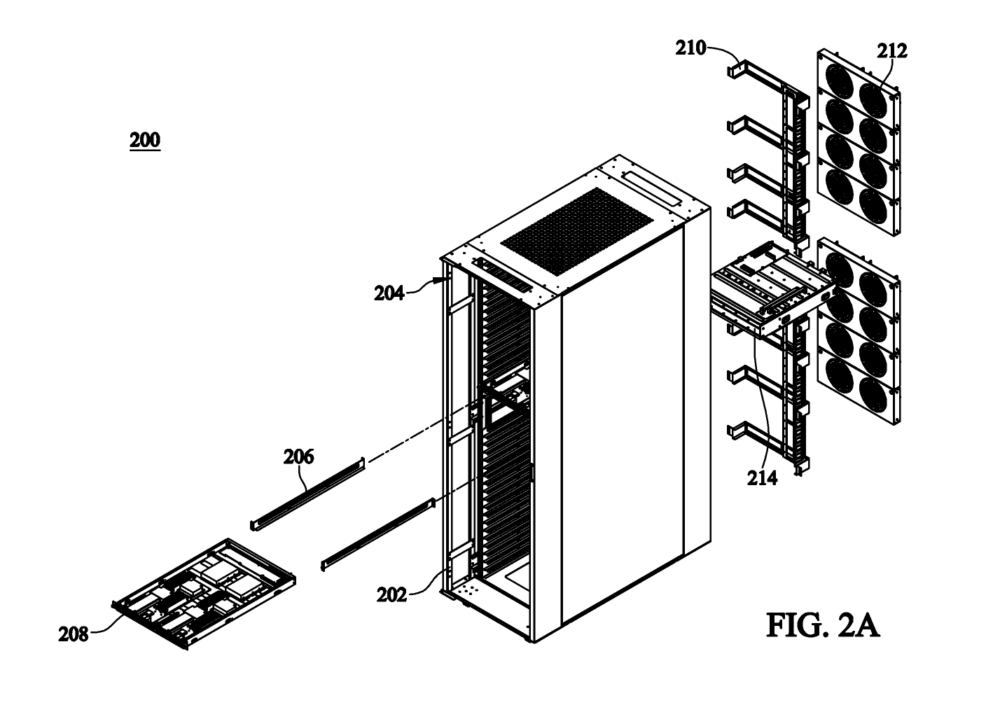

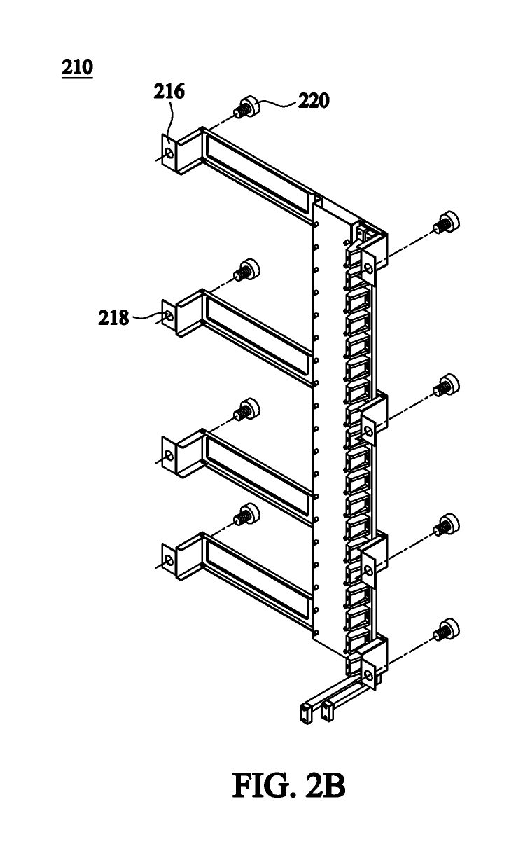

FIG. 2A is an exploded view of a server rack according to an embodiment of this disclosure. As shown in FIG. 2A, the server rack 200 includes plural support pillars 202 which provides structural support of the server rack 200. In general, the support pillars 202 are disposed in the surrounding of the server rack 200, and the support pillars 202 is used to support the server rack 200. Besides, each of the support pillars 202 has plural first mounting holes 204 which are the slide rail mounting holes preferably. The purpose of disposing these first mounting holes 204 is able to fix the slide rail 206 on the server rack 200, thereby allows the servers 208 is disposed into the server rack 200 by the slide rail 206. Moreover, the server rack 200 further includes the bus bar kit 210, the fan cage kit 212 and the MB (mother board) tray kit 214, and in the other embodiment, the server rack 200 further includes the power cage kit (not shown in the figure), but it is not limited herein. The above-mentioned embodiments in this disclosure, these kits are the independent and single package that can be assemble or separate from the server rack 200.

FIG. 2B is a schematic view of the bus bar kit according to the server rack of this disclosure. This embodiment uses the bus bar kit 210 as an example, but in the other embodiment, the fan cage kit 212 or the MB tray kit 214 may also be used as the example, but it is not limited herein. As shown in FIG. 2B, each of the bus bar kits 210 has two mounting portions 216 which extends along a longitudinal direction from two ends of the bus bar kit 210 respectively, and each of the mounting portions 216 has a second mounting hole 218. When the bus bar kit 210 is disposed into the server rack 200, the first mounting holes 204 are corresponding to the second mounting holes 218 respectively. By fixing components 220 passing through the first mounting hole 204 and the second mounting hole 218, the bus bar kit 210 is fixed on the support pillar 202. Similarly, the fan cage kit 212, the MB tray kit 214, or the power cage kit of this disclosure also has the mounting portion 216, and through the mounting portion 216 these kits can be selectively assembled to or separated from the server rack 200. The bus bar kit 210, the fan cage kit 212, or the MB tray kit 214 also can be changed to any suitable position in the server rack 200 thereof according to the actual demand. Besides, the purpose to increase or reduce the amount of the fan cage kit 212 or the MB tray kit 214 can be easily achieved.

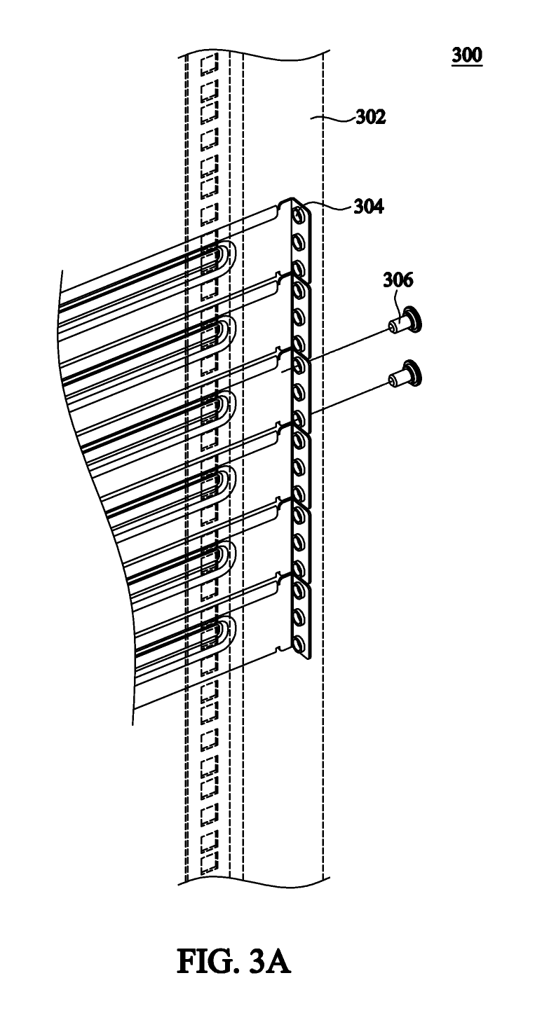

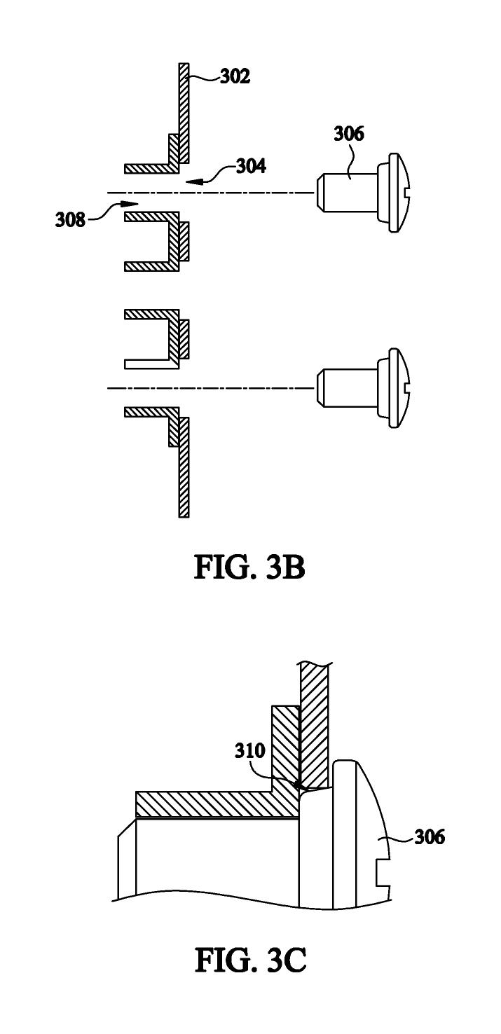

FIG. 3A is a partially schematic view of the embodiment of this disclosure, FIG. 3B is a cross-sectional view of the embodiment of this disclosure, and FIG. 3C is a partially cross-sectional view of FIG. 3B. Referring to FIG. 3A, each of the support pillars 302 of the server rack 300 has plural first mounting holes 304. The first mounting holes 304 are common design existing on the server rack 300 to serve as the slide rail mounting holes to fix the slide rail. Referring to FIG. 3B, by means of the first mounting holes 304, the fixing component 306 and the second mounting holes 308 corresponding with each other, the module kits are able to be fixed on the support pillars 302 of the server rack 300 respectively by the fixing components 306. In the embodiment of this disclosure, the support pillar 302 has three first mounting holes 304, wherein two of the first mounting holes 304 are corresponding to the fixing holes of the conventional server rack, and the other one first mounting hole 304 is corresponding to the second mounting hole 308 of the module kit. While the fixing component 306 passes through the first mounting hole 304 of the support pillar 302 and the second mounting hole 308 of the mounting portion of the module kit, the module kit is locked onto the server rack 300. Moreover, the position and/or amount of the first mounting holes 304 and the second mounting holes 308 can be changed according to the actual requirement. In this embodiment, only one of the second mounting holes 308 is corresponding to the first mounting hole 304 at the top position of the support pillar 302. However, in the other embodiment that at least one second mounting holes 308 can be corresponding to the first mounting hole 304 at any position of the support pillar 302, but it is not limited herein.

As shown in FIG. 3C, the fixing component 306 in the embodiment is a circular screw preferably. The fixing component 306 has an inclined plane 310, and the inclined plane 310 is disposed on top portion of the fixing component 306, wherein the inclined plane 310 has a slope external diameter. The first mounting holes 304 of the server rack 300 are a square mounting hole; through the slope external diameter of the inclined plane 310, the fitness between the module kits and the server rack 300 is enhanced. As shown in FIG. 3C, due to the inclined plane 310 of the fixing component 306, so that the fixing component 306 and the first mounting hole 304 can be jointed tightly.

Besides, each of the mounting portions 216 of the bus bar kit 210 uses the same mounting hole with the support pillar 302 and the slide rail 206. Thus, while the slide rail 206 and the bus bar kit 210 are assembled to the support pillar 302, through guidance of the fixing component 306 the slide rail 206 and the bus bar kit 210 can be fixed on the server rack 300 at the same time, and the slide rail 206 can be disposed at the predetermined position in the server rack 300 accurately, thereby the pins of the MB tray kit 214 electrically insert into the connector of the bus bar kit 210 accurately, so as to avoid the MB tray kit 214 collides with the bus bar kit 210 during the electrically connecting procedure due to the limitation of the tolerance.

In this disclosure, the module kits of the server rack are able to be changed to a suitable position by the above-mentioned structure design, and the amount of the module kits can be easily increased or reduced according to the actual requirement. This disclosure provides the server rack which is configured to simplify the structure by a modular design, and maintaining the server could be more easily in the future.

This disclosure has been disclosed as mentioned-above and it is understood the embodiments are not intended to limit the scope of this disclosure. Moreover, as the contents disclosed herein should be readily understood and can be implemented by a person skilled in the art, all equivalent changes or modifications which do not depart from the spirit of this disclosure should be encompassed by the appended claims.

What is claimed is:

1. A server rack, comprising:
a plurality of support pillars, wherein each of the support pillars has a plurality of first mounting holes;
a plurality of module kits, wherein each of the module kits has at least one mounting portion, and each of the mounting portions has a second mounting hole which corresponding to one of the first mounting holes; and
a plurality of fixing components, passing through the first mounting holes and the second mounting holes respectively, and each of the module kits is fixed on the server rack by the mounting portion.

2. The server rack as claimed in claim 1, wherein the first mounting holes are used to fix a plurality of slide rails, and a plurality of servers are disposed on the slide rails respectively and assembled into the server rack.

3. The server rack as claimed in claim 2, wherein the first mounting hole is a slide rail mounting hole.

4. The server rack as claimed in claim 1, wherein each of the module kits is selected from the group consisting of a bus bar kit, a power cage kit, a fan cage kit and a MB tray kit.

5. The server rack as claimed in claim 1, wherein the mounting portion extends along a longitudinal direction from two ends of the module kit.

6. The server rack as claimed in claim 1, wherein the fixing component is a screw and an inclined plane disposed on a top portion of the screw, and each of the screws respectively passes through the first mounting hole and the second mounting hole by the inclined plane, so as to fix the module kits on the server rack.

7. A server rack, comprising:
a plurality of support pillars, wherein each of the support pillars has a plurality of first mounting holes;
a plurality of module kits, wherein each of the module kits has at least one mounting portion which extends along a longitudinal direction from two ends of the module kit, the mounting portion is selectively assembled to or separated from the support pillar, and each of the mounting portions has a second mounting hole corresponding to one of the first mounting holes; and
a plurality of fixing components, wherein each of the fixing components has an inclined plane disposed on a top portion of the fixing component, the fixing components align and pass through the first mounting holes and the second mounting hole respectively by the inclined plane, so as to fix the module kits on the server rack.

8. The server rack as claimed in claim 7, wherein the fixing component is a circular screw.

9. The server rack as claimed in claim 7, wherein the first mounting hole is a square slide rail mounting hole.

10. The server rack as claimed in claim 7, wherein each of the module kits is selected from the groups consisting of a bus bar kit, a power cage kit, fan cage kit and a mother board tray kit.
